(19) United States
(12) Patent Application Publication
(10) Pub. No.: US 2005/0059191 A1
(43) Pub. Date: Mar. 17, 2005

(54) METHOD OF FABRICATING LOW TEMPERATURE POLYSILICON THIN FILM TRANSISTOR

(76) Inventor: Hui-Chu Lin, Hsin-Chu Hsien (TW)

Correspondence Address: (NAIPC) NORTH AMERICA INTERNATIONAL PATENT OFFICE, P.O. BOX 506, MERRIFIELD, VA, 22116, US

(21) Appl. No.: 10/605,232

(22) Filed: Sep. 17, 2003

(51) Int. Cl. H01L 21/84

(52) U.S. Cl. 438/151

(57) ABSTRACT

First, a substrate with a polysilicon film is provided. Then, a gate insulating layer and a gate are formed on the polysilicon film in sequence. An ion implantation process is performed to form a source and a drain around the gate. After that, a first plasma enhanced chemical vapor deposition (PECVD) process is performed to form a silicon nitride layer over the substrate and the gate. A second plasma enhanced chemical vapor deposition process is then performed to form a TEOS based silicon oxide layer on the silicon nitride layer. A photo-etching process follows to form a contact hole extending through to the source and drain respectively. Then, a conductive layer is filled into the contact holes and electrically connected to the source and drain.

### BACKGROUND OF INVENTION

1. Field of the Invention

The present invention relates to a method of fabricating an interlayer dielectric layer (ILD) of a low temperature polysilicon thin film transistor, and more particularly, to a method of fabricating a low temperature polysilicon thin film transistor that has a composite interlayer dielectric layer.

2. Description of the Prior Art

Nowadays, liquid crystal displays (LCDs) are a mature flat panel display technology. Applications for liquid crystal displays are extensive, including devices such as mobile phones, digital cameras, video cameras, notebooks, and monitors. Due to high quality display requirements and expansion into new application fields, LCD technology is being developed toward high quality, high resolution, high brightness, and low cost. Actively driven low temperature polysilicon thin film transistors (LTPS TFTs) are a breakthrough toward achieving the above objectives.

In the fabrication process of a low temperature polysilicon thin film transistor, an interlayer dielectric layer (ILD) is disposed between the transistors and the corresponding metal wires disposed on the transistors to isolate and protect the electric devices in the display panel. The interlayer dielectric layer has a plurality of contact holes so that the metal wires can be filled into the contact holes and electrically connected to the corresponding transistors. As a result, data signals can be transfer to a source/ drain of the transistors via the corresponding metal wires to control the operation of the pixel electrodes in the display panel.

Please refer to FIG. 1 to FIG. 4, which are schematic diagrams of a conventional method of fabricating an interlayer dielectric layer of a low temperature polysilicon thin film transistor. Although a display panel normally comprises a plurality of low temperature polysilicon thin film transistors, only one low temperature polysilicon thin film transistor is illustrated in the figures for clarity. As shown in FIG. 1, a display panel 10 comprises a substrate 12, such as a glass substrate or a silicon substrate. First, a chemical vapor deposition process or a sputtering process is performed to form an amorphous silicon film of a thickness of about 500 angstroms. An excimer laser annealing (ELA) process is then performed to make the amorphous silicon film crystallize to a polysilicon film 14. After that, a first photo-etching process is performed to pattern the polysilicon film 14. The residual polysilicon film 14 is used as an active area of each low temperature polysilicon thin film transistor, which comprises a source region 18, a drain region 20, and a channel region 22.

As shown in FIG. 2, a chemical vapor deposition process is performed to form a gate insulating layer 24 on the polysilicon film 14. Next, a sputtering process is performed to form a metal layer on the gate insulating layer 24. Then, a second photo-etching process is used to pattern the metal layer and form a gate 26 on the channel region 22.

As shown in FIG. 3, an ion implantation process is performed by using the gate 26 as a mask to form a source 28 in the source region 18 and a drain 30 in the drain region 20. The source 28, the drain 30, and the gate 26 form a low temperature polysilicon thin film transistor 32. To meet the requirements of the TFT, the series resistances of the source and drain must be very low, and so, an activation process is then performed to activate the dopants in the source 28 and the drain 30. It is noted that the activation process not only moves the dopants to the correct lattice location, but also repairs lattice defects caused by the ion implantation process.

As shown in FIG. 4, after the gate 26, the source 28, and the drain 30 of the low temperature polysilicon thin film transistor 32 are formed, a dielectric layer 34 is formed to cover the gate 26 and the gate insulating layer 24. A third photo-etching process follows to form a contact hole 36 in the source region 18 extending to the source 28, and another contact hole 36 in the drain region 20 extending to the drain 30. After that, a conductive layer 38 is filled into the contact holes 36 and used to form the electrical connection of the low temperature polysilicon thin film transistor 32.

The dielectric layer 34 is not only used as a protective layer for preventing the already disposed electric devices from being affected by or affecting subsequent fabrication processes, but also serves as an interlayer dielectric layer for performing the multi-layer connection process. However, current materials used for the dielectric layer cannot meet these two requirements at the same time. Taking the silicon oxide layer and the silicon nitride layer, which are widely used in the fabrication processes of semiconductors and display panels, as an example, the silicon nitride layer has a good protective ability and can restrict passage of moisture and metal ions. However, the silicon nitride layer also readily generates parasitic capacitors because of its high dielectric constant, leading to signal delay that is unsuitable for an interlayer dielectric layer. The silicon oxide layer has a low dielectric constant and does not cause signal delay. However, its protection ability is much worse than the silicon nitride layer, as it cannot protect electric devices disposed beneath.

In addition, in the fabrication process of the silicon oxide layer, silane or tetra-ethyl-ortho-silicate (TEOS) can be alternatively used as a silicon source to form silicon oxide layers with different characteristics, which are a silanebased silicon oxide layer or TEOS-based silicon oxide layer. The former contains a certain percentage of hydrogen atoms that can be used as a hydrogen source to perform a hydrogenating process for repairing defects in the polysilicon film. However, it has a low step coverage ability so that voids occur easily in the deposition process. The latter has a good step coverage ability in the deposition process, but cannot serve as a hydrogen source. This means that a subsequent hydrogen process is needed for an additional hydrogen source requiring much more equipment and manufacturing time.

As mentioned above, among all conventional methods, none can successfully make an interlayer dielectric layer that has a good interface characteristic, high threshold voltage stability, good protective ability against moisture and metal ions, and high break-down voltage. Thus, there is a strong need to develop a method of fabricating a low temperature polysilicon thin film transistor having the aforementioned advantages.

### SUMMARY OF INVENTION

It is therefore a primary objective of the claimed invention to provide a method of fabricating a low temperature polysilicon thin film transistor that comprises a composite interlayer dielectric layer so as to solve the aforementioned problems.

In a preferred embodiment, the claimed invention provides a method of fabricating an interlayer dielectric layer of a low temperature polysilicon thin film transistor. First, a substrate with a polysilicon film is provided. Then, a gate insulating layer and a gate are formed on the polysilicon film in sequence. An ion implantation process is performed to form a source and a drain surrounded the gate. After that, a first plasma enhanced chemical vapor deposition (PECVD) process is performed to form a silicon nitride layer over the substrate and the gate. A second plasma enhanced chemical vapor deposition process is then performed to form a TEOS based silicon oxide layer on the silicon nitride layer. A photo-etching process follows to form a contact hole on the source and another contact hole on the drain respectively. Then, a conductive layer is filled into the contact holes and electrically connected to the source and drain.

It is an advantage of the claimed invention that the method forms a silicon nitride layer to increase the protective ability against moisture and metal ions and to provide a hydrogen source, and then forms a TEOS based silicon oxide layer to provide a good step coverage ability and reduce the dielectric constant of the composite interlayer dielectric layer for avoiding the presence of parasitic capacitors. Thus, the electric performance and the stability of the low temperature polysilicon thin film transistor can be improved effectively.

These and other objectives of the claimed invention will no doubt become obvious to those of ordinary skill in the art after reading the following detailed description of the preferred embodiment which is illustrated in the various figures and drawings.

### BRIEF DESCRIPTION OF DRAWINGS

FIG. 1 to FIG. 4 are schematic diagrams offabricating an interlayer dielectric layer of a low temperature polysilicon thin film transistor according to the prior art.

FIG. 5 to FIG. 9 are schematic diagrams offabricating an interlayer dielectric layer of a low temperature polysilicon thin film transistor according a first embodiment of the present invention.

FIG. 10 to FIG. 12 are schematic diagrams offabricating an interlayer dielectric layer of a low temperature polysilicon thin film transistor according a second embodiment of the present invention.

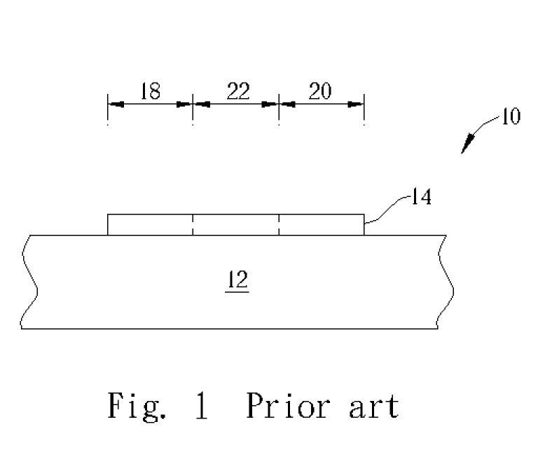

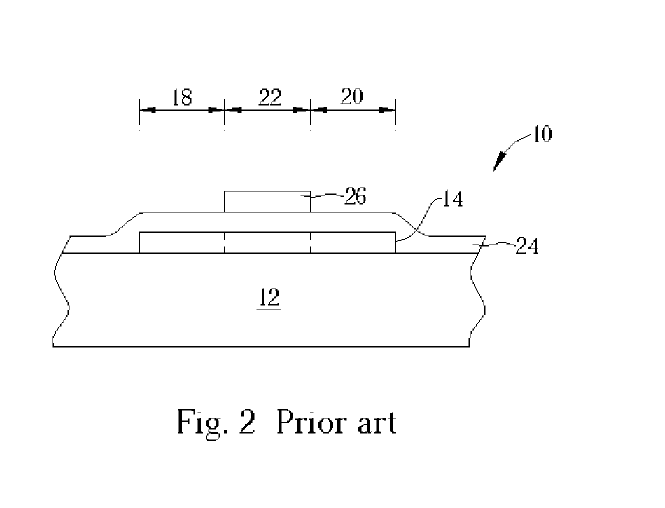

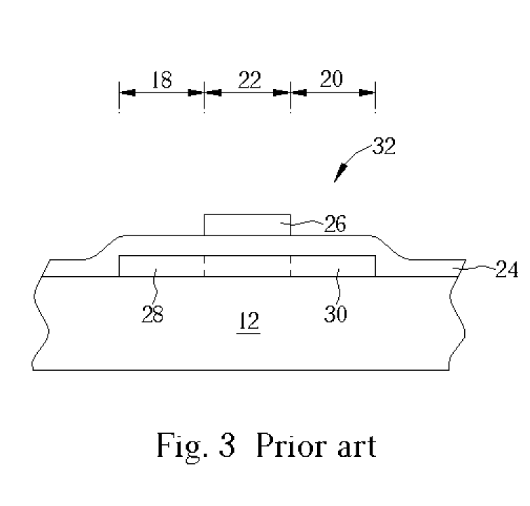

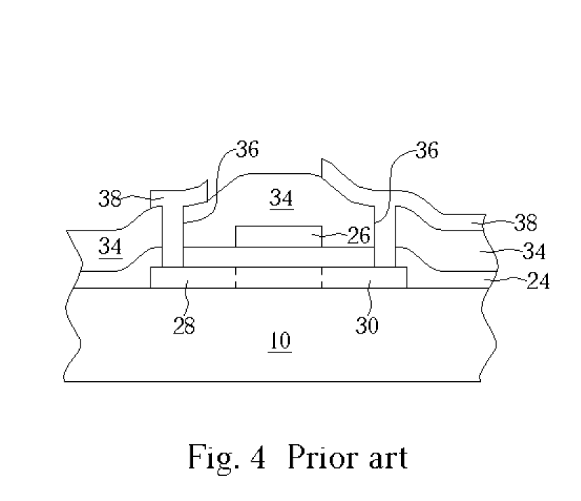

### DETAILED DESCRIPTION

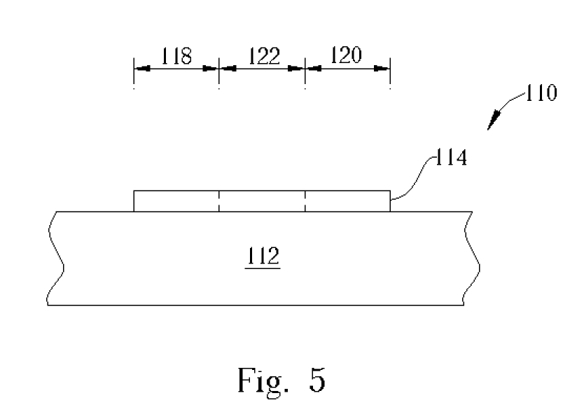

Please refer to FIG. 5 to FIG. 9, which are schematic diagrams offabricating an interlayer dielectric layer of a low temperature polysilicon thin film transistor according a first embodiment of the present invention. As mentioned above, though a display panel normally comprises a plurality of low temperature polysilicon thin film transistors, only one low temperature polysilicon thin film transistor is illustrated in the following diagrams for clarity. As shown in FIG. 5, a display panel 110 comprises a substrate 112 on the surface thereof. The substrate 112 is a glass substrate or a silicon substrate. A chemical vapor deposition process or a sputtering process is performed to form an amorphous silicon film (not shown) with a thickness of 500 angstrom on a display panel 110. An excimer laser annealing process follows to make the amorphous silicon film crystallize to a polysilicon film 114. Then, a first photo-etching process is performed to pattern the polysilicon film and leave a predetermined portion for forming the low temperature polysilicon thin film transistors. The polysilicon film 114 comprises a source region 118, a drain region 120, and a channel region 122 on the surface of the polysilicon film 114.

As mentioned, since the quality of the amorphous silicon thin film (not shown) is a determining factor for the characteristics of the subsequently formed polysilicon layer 114, all of the parameters for the amorphous silicon thin film deposition process need to be strictlycontrolled. An amorphous silicon thin film with low hydrogen content, high thickness uniformity, and low surface roughness is thus formed. Moreover, the amorphous silicon thin film is melted and re-crystallized rapidly through absorption of deep ultraviolet light during the excimer laser annealing process to form the polysilicon layer 114. Such a quick absorption due to the short laser pulse only affects the surface of the amorphous silicon thin film and will not affect the substrate 112. Hence, the substrate 112 is kept at a low temperature state.

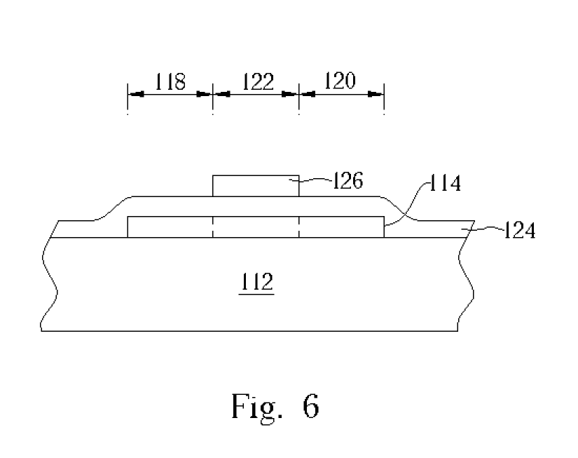

As shown in FIG. 6, a chemical vapor deposition process is thereafter performed to form a gate insulating layer 124 on the polysilicon film 114 surface. Then, a sputtering process is performed to form a metal layer and a second photo-etching process follows to pattern the metal layer and form a gate 126 on the channel region 122. In a preferred embodiment of the present invention, the gate insulating layer 124 comprises a silicon nitride layer, a silicon oxide layer, or a composite structure composed of a silicon nitride layer and a silicon oxide layer. The metal layer may be a tungsten (W) layer, an aluminum (Al) layer, a chrome (Cr) layer, or alloys composed of such materials.

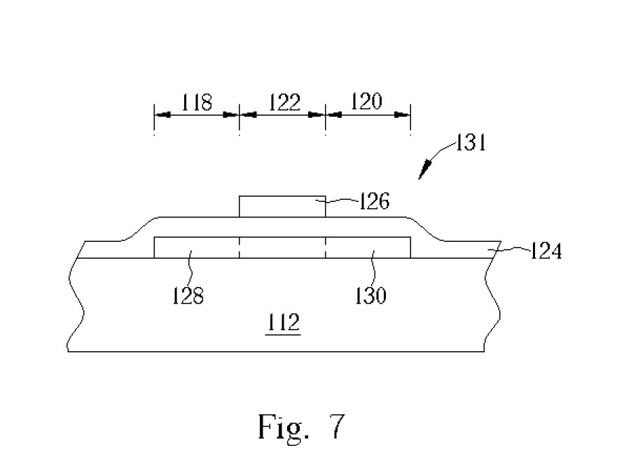

As shown in FIG. 7, an ion implantation process is performed by using the gate 126 as a mask to form a source 128 in the source region 118 and a drain 130 in the drain region 120 of the polysilicon film 114. The source 128, the drain 130, and the gate 126 form a low temperature polysilicon thin film transistor 131. After that, an activation process is performed to highly activate dopants in the source 128 and the drain 130. The activation process not only moves the ions to the correct lattice sites, but also repairs lattice defects incurred from the ion implantation process.

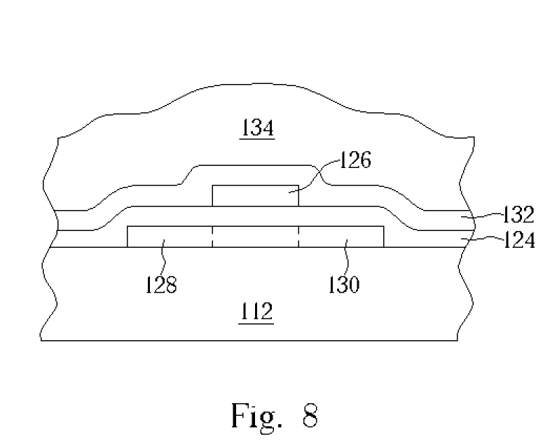

As shown in FIG. 8, a first plasma enhanced chemical vapor deposition (PECVD) process is performed by inputting silane, ammonia (NH₃), and nitrogen (N₂) to form a silane based silicon nitride layer (SiNₓ layer, 1.0<×<1.6) 132 covering on the gate 126 and the gate insulating layer 234. Then, a second PECVD process is performed by inputting tetra-ethyl-ortho-silicate (TEOS) and oxygen to form a tetra-ethyl-ortho-silicate based silicon oxide layer (TEOS-based SiOₓ layer) 134 on the silicon nitride layer 132. The silane based silicon nitride layer 132 and the TEOS based silicon oxide layer 134 together form a composite interlayer dielectric layer.

It is noted that since the dielectric constant of the silicon nitride layer 132 is much higher than the dielectric constant of the silicon oxide layer 134, the present invention method can effectively avoid an overly high capacitance value in the composite interlayer dielectric layer, which leads to signal delay, by adjusting the thickness for the silicon oxide layer 134 to be greater than that of the silicon nitride layer 132. In a preferred embodiment of the present invention, a thickness of the silicon nitride layer 132 is in a range of 500 to 3500 angstroms and a thickness of the silicon oxide layer 134 is in a range of 2500 to 10000 angstroms. In addition, the first PECVD process and the second PECVD process can be performed in a single wafer type chamber continuously or in different single wafer type chambers.

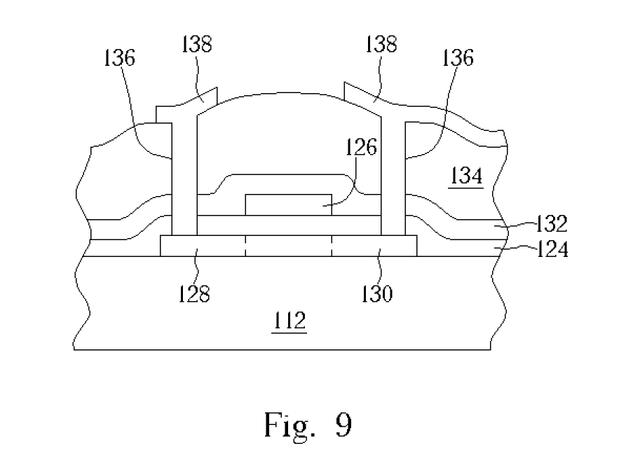

As shown in FIG. 9, a third photo-etching process is performed to form a contact hole 136 on the source region 118 and another contact hole 136 on the drain region 120. Then, a conductive layer 138 is filled into the contact holes 136 and electrically connected to the source 128 and the drain 130 to complete the electrical connection of the low temperature polysilicon thin film transistor 131.

A major feature of the present invention is using one silane based silicon nitride layer 132 and one TEOS based silicon oxide layer 134 as the interlayer dielectric layer covering the low temperature polysilicon thin film transistor 131. Thus, a hydrogen source for a subsequent hydrogenating process can be provided by the silicon nitride layer 132 and the characteristic of the interlayer dielectric layer, such as step coverage ability, dielectric constant, and breakdown voltage, can be improved greatly due to the presence of the TEOS silicon oxide layer 134, improving the device performance and reliability.

Although only a top gate type of low temperature polysilicon thin film transistor is disclosed in the embodiment above, the present invention it not restricted to a top gate type of low temperature polysilicon thin film transistors but can be applied to the interlayer dielectric layer of other devices, such as a bottom gate type of low temperature polysilicon thin film transistor.

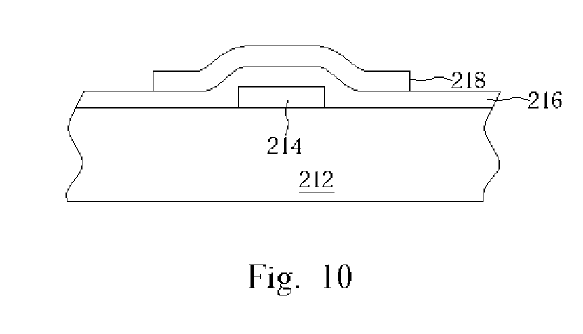

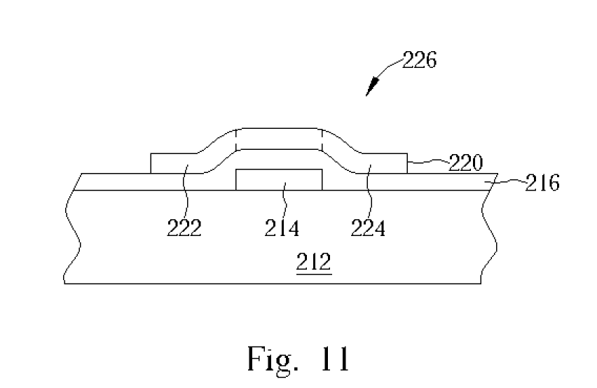

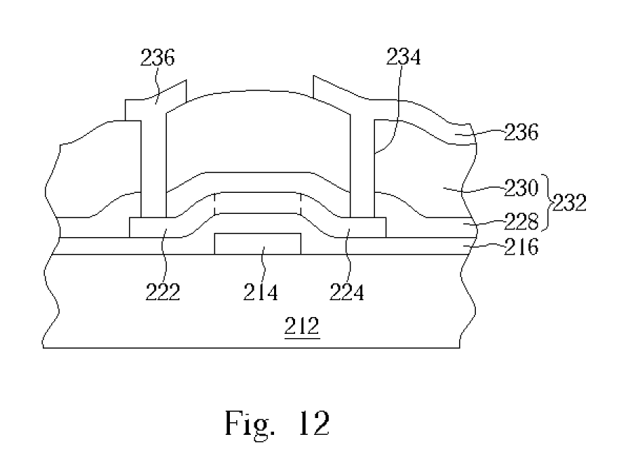

Please refer to FIG. 10 to FIG. 12, which are schematic diagrams offabricating an interlayer dielectric layer of a low temperature polysilicon thin film transistor according a second embodiment of the present invention. As shown in FIG. 10, first, a gate 214 is formed on a substrate 212. Then, a gate insulating layer 216 and an amorphous silicon film 218 are formed on the gate 214 and the substrate 212 in sequence. Next, as shown in FIG. 11, an excimer laser annealing process is performed to make the amorphous silicon film 218 melted and crystallize to a polysilicon film 220. An ion implantation process is performed thereafter to form a source 222 and a drain 224 in the polysilicon film 220 to form a bottom gate type of a low temperature polysilicon thin film transistor 226. As shown in FIG. 12, in the same manner, a silane based silicon nitride layer 228 and a TEOS based silicon oxide layer 230 forms a composite interlayer dielectric layer 232 positioned on the low temperature polysilicon thin film transistor 226. Then, a contact hole 234 is formed on the source 222 and another contact hole 234 is formed on the drain 224. After that, a conductive layer 236 is filled into the contact holes 234 to complete the electrical connection of the low temperature polysilicon thin film transistor 226.

In contrast with the prior art method,the present invention forms a silicon nitride layer and a TEOS based silicon oxide layer in turn to construct a composite interlayer dielectric layer. Thus, the present invention not only provides a high step coverage ability, high breakdown voltage, and good moisture and metal protective ability, but also provides a hydrogen source for a subsequent hydrogenating process so as to improve the electric performance and reliability of the low temperature polysilicon thin film transistor.

Those skilled in the art will readily observe that numerous modifications and alterations of the device may be made while retaining the teaching of the invention. Accordingly, the above disclosure should be construed as limited only by the metes and bounds of the appended claims.

1. A method of fabricating a low temperature polysilicon (LTPS) thin film transistor (TFT), the method comprising following steps:
providing a substrate;
forming a polysilicon film on the substrate, the polysilicon film defined with a source region, a drain region, and a channel region between the source region and the drain region;
forming a gate insulating layer on the substrate; forming a gate on the substrate;
performing an ion implantation process to form a source in the source region and a drain in the drain region;
forming a silicon nitride layer covering the gate and the polysilicon film; and
forming a TEOS based silicon oxide layer on the silicon nitride layer.

2. The method of claim 1 further comprising following steps:
performing a photo-etching process to form a contact hole on the source and another contact hole on the drain; and filling a conductive layer in the contact holes, the conductive layer being electrically connected to the source and the drain.

3. The method of claim 1 wherein the method of forming the polysilicon film comprises following steps:
forming an amorphous silicon film on the substrate; and performing an excimer laser annealing process to make the amorphous silicon film crystallize to the polysilicon film.

4. The method of claim 1 wherein the silicon nitride layer is a silane based silicon nitride layer.

5. The method of claim 4 wherein the silicon nitride layer comprises 20% to 40% hydrogen atoms and serves as a hydrogen source of a hydrogenating process.

6. The method of claim 1 wherein the gate is a metal gate.

7. The method of claim 1 wherein the silicon oxide has a thickness in a range of 2500 to 10000 angstroms.

8. The method of claim 1 wherein the silicon nitride has a thickness in a range of 500 to 3500 angstroms.

9. The method of claim 1 wherein the method forms the silicon nitride layer by performing a first plasma enhanced chemical vapor deposition (PECVD) process.

10. The method of claim 9 wherein the method forms the silicon oxide layer by performing a second plasma enhanced chemical vapor deposition process.

11. The method of claim 10 wherein the first PECVD process and the second PECVD process are performed in the same reacting chamber.

12. The method of claim 10 wherein the first PECVD process and the second PECVD process are performed in different reacting chambers.

13. The method of claim 1 wherein the low temperature polysilicon thin film transistor is a top gate low temperature polysilicon thin film transistor or a bottom gate low temperature polysilicon thin film transistor.
